(19) United States
(12) Patent Application Publication
(10) Pub. No.: US 2005/0022862 A1
(43) Pub. Date: Feb. 3, 2005

(54) Methods and apparatus for fabricating solar cells

(76) Inventors: Michael J. Cudzinovic, Sunnyvale, CA (US); Neil Kaminar, Boulder Creek, CA (US); Luca Pavani, Fermo (IT); David D. Smith, San Jose, CA (US)

Correspondence Address: OKAMOTO & BENEDICTO, LLP, P.O. BOX 641330, SAN JOSE, CA, 95164, US

(21) Appl. No.: 10/633,212

(22) Filed: Aug. 1, 2003

(51) Int. Cl. H01L 31/00

(52) U.S. Cl. 136/256; 438/98

(57) ABSTRACT

In one embodiment, a solar cell is fabricated using an ink pattern as a mask for a processing step. The ink pattern may comprise an ink that is substantially devoid of particles that may scratch a surface on which the ink pattern is formed. The ink pattern may be formed by screen printing. In one embodiment, the ink pattern is formed on an oxide layer and comprises an ink that is substantially free of silicon dioxide particles. The ink pattern may be employed as an etching or deposition mask, for example.

### BACKGROUND OF THE INVENTION

1. Field of the Invention

The present invention relates generally to solar cells, and more particularly but not exclusively to methods and apparatus for fabricating solar cells.

2. Description of the Background Art

Solar cells are well known devices for converting solar radiation to electrical energy. They may be fabricated on a semiconductor wafer using semiconductor processing technology. Generally speaking, a solar cell may be fabricated by forming p-doped and n-doped regions in a silicon substrate. Solar radiation impinging on the solar cell creates electrons and holes that migrate to the p-doped and n-doped regions, thereby creating voltage differentials between the doped regions. In a backside-contact solar cell, the doped regions are coupled to metal contacts on the backside of the solar cell to allow an external electrical circuit to be coupled to and be powered by the solar cell. Backside-contact solar cells are disclosed in U.S. Pat. Nos. 5,053,083 and 4,927,770, which are both incorporated herein by reference in their entirety.

### SUMMARY

In one embodiment, a solar cell is fabricated using an ink pattern as a mask for a processing step. The ink pattern may comprise an ink that is substantially devoid of particles that may scratch a surface on which the ink pattern is formed. The ink pattern may be formed by screen printing. In one embodiment, the ink pattern is formed on an oxide layer and comprises an ink that is substantially free of silicon dioxide particles. The ink pattern may be employed as a mask in an etching or deposition step, for example.

These and other features of the present invention will be readily apparent to persons of ordinary skill in the art upon reading the entirety of this disclosure, which includes the accompanying drawings and claims.

### DESCRIPTION OF THE DRAWINGS

FIG. 1 schematically illustrates a technique for forming a mask on a solar cell in accordance with an embodiment of the present invention.

FIGS. 2A-2E schematically illustrate the fabrication of a solar cell in accordance with an embodiment of the present invention.

The use of the same reference label in different drawings indicates the same or like components. Drawings are not necessarily to scale unless otherwise noted.

### DETAILED DESCRIPTION

In the present disclosure, numerous specific details are provided such as examples of apparatus, materials, process steps, and structures to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

In accordance with an embodiment of the present invention, a solar cell is fabricated using ink patterns as masks for etching steps. An ink pattern may comprise an ink that is substantially free of particles that may scratch a layer of material directly underneath the ink pattern. Preferably, the ink is devoid of particles that are as hard or harder than the layer of material underneath the ink pattern. This prevents the ink from scratching the surface of the underlying material, which could result in defects that could adversely affect the operation and performance of the solar cell.

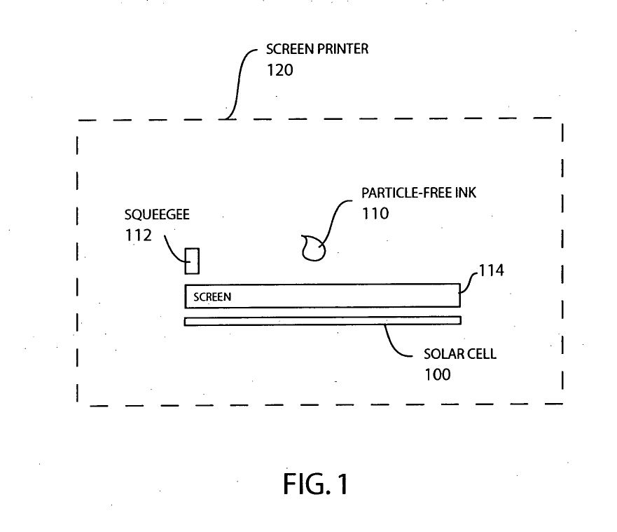

FIG. 1 schematically illustrates a technique for forming a mask on a solar cell in accordance with an embodiment of the present invention. In FIG. 1, a solar cell 100 is in the process of being fabricated. The fabrication of solar cells is also described in the following commonly-assigned disclosures, which are incorporated herein by reference in their entirety: U.S. application Ser. No. 10/412,638, entitled “Improved Solar Cell and Method of Manufacture,” filed on Apr. 10, 2003 by William P. Mulligan, Michael J. Cudzinovic, Thomas Pass, David Smith, Neil Kaminar, Keith McIntosh, and Richard M. Swanson; and U.S. application Ser. No. 10/412,711, entitled “Metal Contact Structure For Solar Cell And Method Of Manufacture,” filed on Apr. 10, 2003 by William P. Mulligan, Michael J. Cudzinovic, Thomas Pass, David Smith, and Richard M. Swanson.

In the example of FIG. 1, screen printer 120 may be a commercially available screen printer such as those of the type available from Affiliated Manufacturing, Inc. (AMI) of North Branch, N.J. or Baccini Spa of Italy. In one embodiment, screen printer 120 comprises the AMI 3230 screen printer from Affiliated Manufacturing, Inc. Other screen printers may also be used without detracting from the merits of the present invention. In screen printer 120, solar cell 100 is placed on a stage and under a screen 114. Screen 114 contains a pattern to be printed on solar cell 100. Screen 114 and solar cell 100 are aligned such that the pattern is correctly positioned over solar cell 100. A particle-free ink 110 is then applied on screen 114. A squeegee 112 may be employed to push particle-free ink 110 through screen 114, thereby forming an ink pattern on solar cell 100. In one embodiment, the ink pattern serves as a mask for an etching step. Depending on the specific particle-free ink 110 employed, the ink pattern may have to be cured. For example, the ink pattern may be cured by exposing it to ultraviolet light (UV-cured ink) or heat (thermally-cured ink).

Inks employed in screen printing are thixotropic in that they flow while pressure is applied to push them through the screen and then firm up after the pressure is released. Most inks thus include a binding agent to allow them to firm up. The inventors found that some binding agents have a tendency to damage a surface of the solar cell on which the ink pattern is formed. For example, inks that employ silicon dioxide as a binding agent have a tendency to scratch the surface of an oxide layer. Although scratches on the surface of an oxide layer may not present a significant problem in some applications, these scratches may eventually result in pits that could damage a solar cell. Accordingly, ink 110 is “particle-free” in that it is substantially devoid of particles that may scratch a surface on solar cell 100 on which the ink pattern is formed.

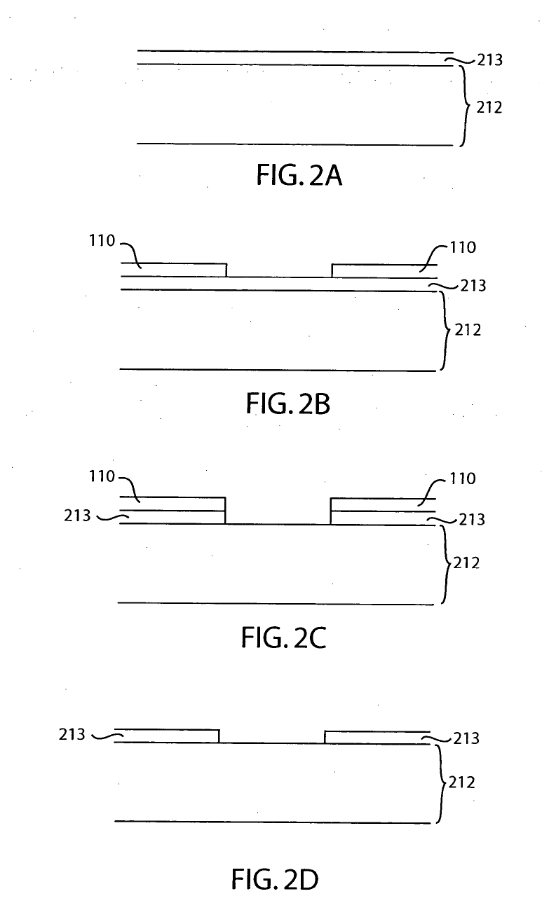

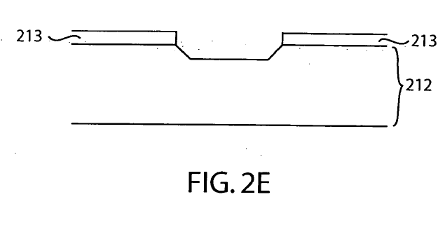

FIGS. 2A-2D schematically illustrate the fabrication of a solar cell in accordance with an embodiment of the present invention. In FIG. 2A, an oxide layer 213 is formed on a silicon material 212. Oxide layer 213 may comprise thermally grown oxide. In one embodiment, silicon material 212 comprises a silicon substrate. Depending on the application, silicon material 212 may also be a layer of silicon material that overlies other layers of materials not specifically shown.

In one embodiment, the solar cell being fabricated is a backside-contact solar cell. In that embodiment, the side of silicon material 212 facing oxide layer 213 is the backside of the solar cell, while the other side of silicon material 212 is the “sun” or front side of the solar cell. Electrical connections to the p-doped and n-doped regions of the solar cell (not shown) may be formed through the backside of the solar cell. The aforementioned U.S. application Ser. Nos. 10/412,638 and 10/412,711 describe backside-contact solar cells that may benefit from embodiments of the present invention. It should be understood, however, that the present invention is not so limited and may be employed in the fabrication of solar cells in general.

In FIG. 2B, an ink pattern comprising particle-free ink 110 is formed on oxide layer 213. In the example of FIG. 2B, particle-free ink 110 is substantially devoid of silicon dioxide particles to prevent scratching of underlying oxide layer 213. The inventors found that etchants of a subsequently performed silicon etch may penetrate these scratches and form pits on the surface of oxide layer 213. In one embodiment, particle-free ink 110 is of the same type as the Coates ER-3070 ink available from Coates Screen of St. Charles, Ill. The composition of particle-free ink 110 may be varied depending on the material on which particle-free ink 110 is applied. Preferably, particle-free ink 110 is substantially devoid of particles that are as hard or harder than the underlying material.

In FIG. 2C, oxide layer 213 is etched using the ink pattern comprising particle-free ink 110 as a mask. Oxide layer 213 may be wet etched using buffered hydrofluoric acid.

In FIG. 2D, the ink pattern is stripped off oxide layer 213. In one embodiment where the ink pattern comprises the Coates ER-3070 ink, the ink pattern may be removed by dipping it in a caustic solution.

In FIG. 2E, silicon material 212 is subsequently etched using oxide layer 213 as a mask. Silicon material 212 may be etched using conventional silicon etchants. For example, silicon material 212 may be wet etched by dipping it in concentrated potassium hydroxide (KOH). The use of particle free ink 110 advantageously helps prevent the ink pattern from damaging the surface of oxide layer 213, thereby helping prevent silicon etchants from forming pits on oxide layer 213 and adversely affecting the operation and performance of the solar cell.

The examples of FIGS. 2A-2E illustrate the use of an ink pattern as a mask for the etching of an oxide layer in a solar cell. In light of the present disclosure, one of ordinary skill in the art may employ similar ink patterns as masks for etching other types of materials in a solar cell. The printing of these ink patterns, along with other solar cell processing techniques, may be employed to complete the fabrication of a solar cell. For example, from FIG. 2E, the remaining structures of the solar cell being fabricated may be formed conventionally or as described in U.S. application Ser. Nos. 10/412,638 and 10/412,711.

Furthermore, in light of the present disclosure, those of ordinary skill in the art will appreciate that the ink patterns disclosed herein may also be employed as masks in solar cell fabrication steps other than etching. For example, the ink patterns may be employed as masks for deposition steps including electroplating and spin coating. The ink patterns may also be generally employed as a protective coating in other solar cell fabrication steps.

Techniques for fabricating a solar cell have been disclosed. While specific embodiments of the present invention have been provided, it is to be understood that these embodiments are for illustration purposes and not limiting. Many additional embodiments will be apparent to persons of ordinary skill in the art reading this disclosure.

1. A method of fabricating a solar cell, the method comprising:
forming an ink pattern on a first layer, the ink pattern comprising an ink that is substantially devoid of particles that can scratch a surface of the first layer; and
etching the first layer using the ink pattern as a mask.

2. The method of claim 1 wherein the ink is substantially devoid of silicon dioxide.

3. The method of claim 2 wherein the first layer comprises an oxide layer.

4. The method of claim 1 wherein the ink pattern is formed by screen printing.

5. The method of claim 1 wherein the etching of the first layer exposes a silicon material.

6. The method of claim 1 wherein the solar cell is a backside-contact solar cell.

7. The method of claim 1 further comprising:
removing the ink pattern off the first layer; and
performing an etch of a silicon material.

8. The method of claim 7 wherein the first layer comprises an oxide layer and the ink is substantially devoid of silicon dioxide.

9. A method of fabricating a solar cell, the method comprising:
forming an oxide layer over a silicon material;
screen printing an ink pattern over the oxide layer, the ink pattern comprising an ink that is substantially free of particles that can scratch a surface of the oxide layer; and
etching portions of the oxide layer not covered by the ink pattern.

10. The method of claim 9 wherein the ink is substantially free of silicon dioxide particles.

11. The method of claim 9 wherein the oxide layer comprises thermally grown oxide.

12. The method of claim 9 further comprising:
removing the ink pattern; and
etching portions of a silicon layer exposed by the etching of the oxide layer.

13. The method of claim 9 wherein the solar cell is a backside-contact solar cell.

14. A method of manufacturing a solar cell, the method comprising:
printing an ink pattern over a first layer, the ink pattern comprising an ink that is substantially devoid of particles that can scratch a surface of the first layer; and
etching portions of the first layer not covered by the ink pattern.

15. The method of claim 14 wherein the ink is substantially devoid of silicon dioxide particles.

16. The method of claim 14 wherein the first layer comprises an oxide layer.

17. The method of claim 14 further comprising:
stripping off the ink pattern; and
etching a silicon material.

18. The method of claim 14 wherein the printing of the ink pattern is by screen printing.

19. The method of claim 14 wherein the first layer comprises an oxide layer and the etching of the first layer exposes a silicon material.

20. The method of claim 14 wherein the solar cell is a backside-contact solar cell.

21. A method of forming a protective coating over a solar cell material, the method comprising:
forming an ink pattern on a layer of a solar cell, the ink pattern comprising an ink that is substantially devoid of particles that can scratch a surface of the layer; and
performing a processing step on the solar cell using the ink pattern as a mask.

22. The method of claim 21 wherein the processing step comprises etching of a material of the solar cell.

23. The method of claim 21 wherein the processing step comprises deposition of a material on the solar cell.

24. The method of claim 21 wherein the layer comprises an oxide layer.

25. The method of claim 21 wherein the ink pattern is formed by screen printing.
